(19) United States
(12) Patent Application Publication
(10) Pub. No.: US 2023/0227273 A1
(43) Pub. Date: Jul. 20, 2023

(54) SUBSTRATE LOADER

(71) Applicant: Ming-Sheng Chen, New Taipei City (TW)

(72) Inventor: Ming-Sheng Chen, New Taipei City (TW)

(73) Assignee: STEK CO., LTD., New Taipei City (TW)

(21) Appl. No.: 18/154,097

(22) Filed: Jan. 13, 2023

(30) Foreign Application Priority Data
Jan. 18, 2022 (TW) 111101956

(51) Int. Cl. B65G 47/92; H02N 13/00

(52) U.S. Cl. CPC B65G 47/92; H02N 13/00

(57) ABSTRACT

A loader includes a pre-aligner and a transporter. The pre-aligner includes a base, a moving mechanism, a platform and a sensing unit. The moving mechanism includes an axle inserted in the base. The platform is coaxially connected to the axle and formed with a fetching face operable for generating an electrostatic field to attract a substrate. The sensing unit is located on the base and operable for sensing an orienting portion of the substrate. The transporter includes a fork formed with a fetching face operable for generating an electrostatic field to attract the substrate.

### BACKGROUND OF INVENTION

### 1. Field of Invention

The present invention relates to a substrate and, more particularly, to a loader for loading a substrate as thin as 200 micrometers or thinner.

### 2. Related Prior Art

Various pieces of equipment are used to execute tasks on a substrate such as inspection, imaging, printing, irradiation with laser, and cutting. Each piece of equipment is used to execute only one of the tasks. Hence, the substrate is moved from one piece of equipment to another piece of equipment. The substrate will suffer grave and irreparable defects and must be disposed of if any misalignment occurs in the movement.

A loader is often used to load and unload the substrate. The loader includes a transporter and a pre-aligner. The transporter is used to move the substrate between load/unload ports of the pieces of equipment, the pre-aligner and a workbench.

The substrate is often a composite substrate made of various types of metal that exhibit different values of ductility. Hence, the substrate often suffers warpage after grinding and polishing when the thickness of the substrate is smaller than 200 μm, 100 μm or even 50 μm and the diameter of the substrate is larger than 8, 12 or even more inches.

Referring to FIG. 1, a substrate 100 is laid on a platform 200 and moved. The platform 200 includes orifices 201 for sucking the substrate 100. When suffering grave warpage, the substrate 100 cannot properly cover the orifices 201 so that the orifices 201 cannot properly suck the substrate 100. Misalignment could occur due to such improper suction. In the worst scenario, the substrate 100 could be tossed from the platform 200 during rotation of the platform 200. Moreover, should the suction be excessively intense, the substrate 100 could suffer cracks that would affect the quality and yield of the substrate 100.

The present invention is therefore intended to obviate or at least alleviate the problems encountered in the prior art.

### SUMMARY OF INVENTION

It is an objective of the present invention to provide a loader for firmly holding a substrate.

It is another objective of the present invention to provide a loader for firmly holding a substrate without any risk of damaging the substrate.

It is another objective of the present invention to provide a loader for flattening a substrate for effective pre-alignment.

To achieve the foregoing objectives, the loader includes a pre-aligner and a transporter. The pre-aligner includes a base, a moving mechanism, a platform and a sensing unit. The moving mechanism includes an axle inserted in the base. The platform is coaxially connected to the axle and formed with a fetching face operable for generating an electrostatic field to attract a substrate. The sensing unit is located on the base and operable for sensing an orienting portion of the substrate. The transporter includes a fork formed with a fetching face operable for generating an electrostatic field to attract the substrate.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a side view of a side view of a portion of a conventional pre-aligner vacuum sucking a substrate;

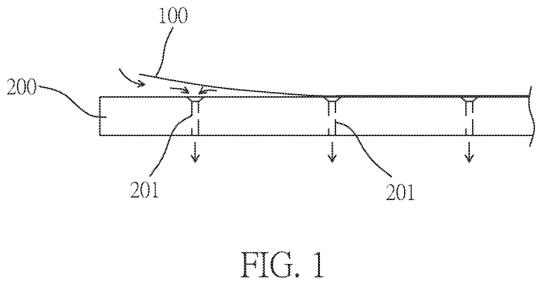

FIG. 2 is a perspective view of a loader according to the preferred embodiment of the present invention;

FIG. 3 is a perspective view of a pre-aligner and a transporter of the loader shown in FIG. 2;

FIG. 4 is a cross-sectional view of the pre-aligner and the transporter mechanism shown in FIG. 3;

FIG. 5 is a top view of the pre-aligner shown in FIG. 4; FIG. 6 is a flow chart of a method for operating the pre-aligner shown in FIG. 3;

FIG. 7 is a cross-sectional view of the pre-aligner and the transporter in another position than shown in FIG. 4;

FIG. 8A is a cross-sectional view of a substrate laid on a platform of the pre-aligner shown in FIG. 7; and

FIG. 8B is a cross-sectional view of the substrate in another position than shown in FIG. 8A.

### DETAILED DESCRIPTION OF EMBODIMENTS

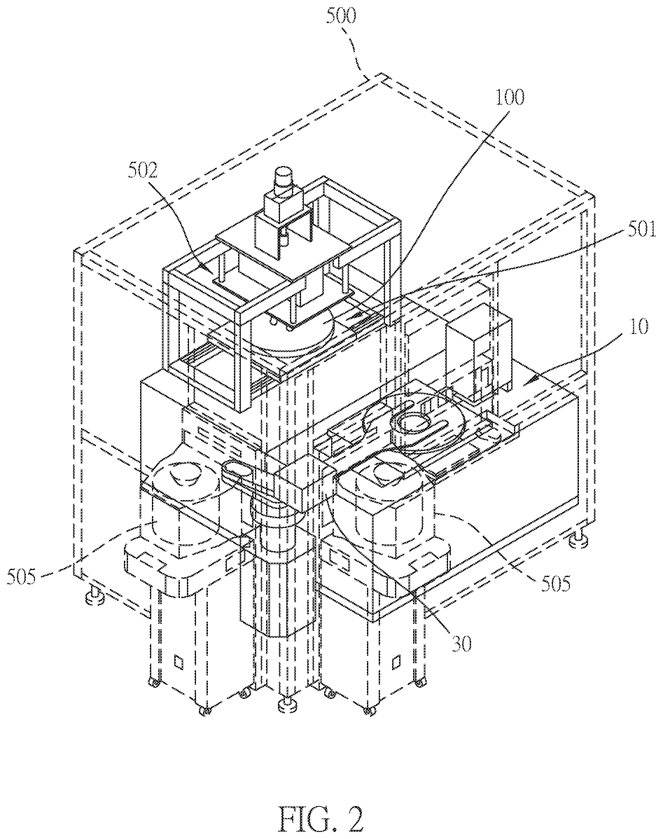

Referring to FIG. 2, a loader includes a pre-aligner 10 and a transporter 30 according to a first embodiment of the present invention. The loader can be a stand-alone apparatus or a part of a machine 500 for processing a substrate 100. The machine 500 is operable to inspect, cut, laser-irradiate and mounting the substrate 100 for example. The machine 500 includes a workbench 501 for supporting the substrate 100, a working module 502 for processing the substrate 100, and load/unload port 505 via which the substrate 100 is load onto or un-load from the workbench 501. The transporter 30 is operable to move the substrate 100 between the workbench 501, the load/unload port 505 and the pre-aligner 10.

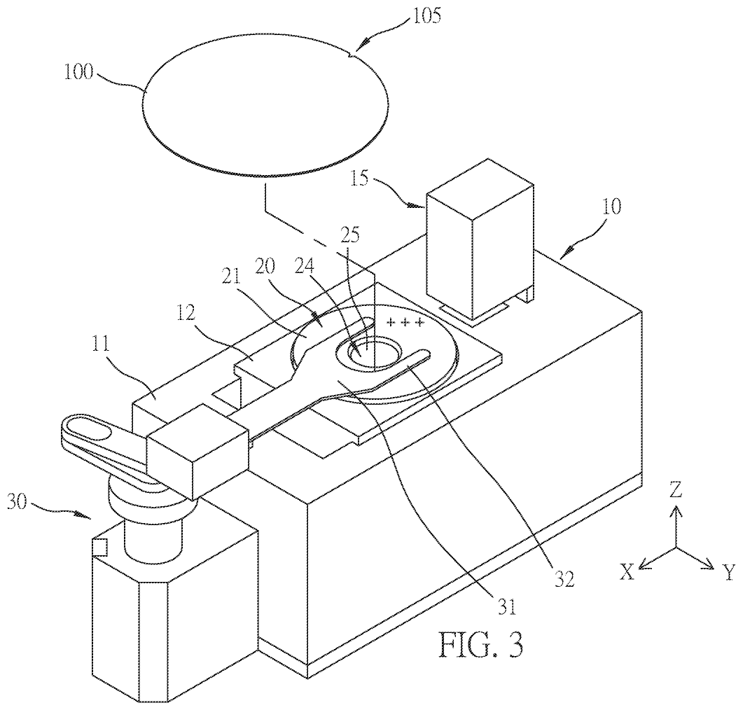

Referring to FIG. 3, a pre-aligner 10 includes a base 11, a moving mechanism 12, a sensing unit 15 and a platform 20 according to a first embodiment of the present invention. The pre-aligner 10 pre-aligns a substrate 100 formed with an orienting portion 105 that includes a notch at a substantially circular edge. However, the orienting portion 105 can include a flat instead of the notch in another embodiment.

The base 11 is a hollow element located in the machine 500. The moving mechanism 12 is inserted in the base 11. The sensing unit 15 is supported on the base 11. The translating unit of the moving mechanism 12 moves the platform 20 relative to the sensing unit 15.

The platform 20 includes a fetching face 21 at an upper end. The fetching face 21 is used to contact the substrate 100. Electrodes are arranged on the fetching face 21. The electrodes enable the fetching face 21 to attract the substrate 100 electrostatically, thereby keeping the substrate 100 in position relative to the fetching face 21. A diameter of the platform 20 is smaller than a diameter of the substrate 100 and is larger than one third of the diameter of the substrate 100. The platform 20 does not reach the orienting portion 105 of the substrate 100 as the substrate 100 rests coaxially on the platform 20. However, the platform 20 adequately attracts and flattens the entire substrate 100, including the orienting portion 105.

The moving mechanism 12 includes a rotating unit, a lifting unit and a translating unit. The rotating unit rotates the platform 20. The lifting unit is coaxial with the platform 20. Moreover, the lifting unit is movable up and down relative to the platform 20.

The rotating unit includes an axle 13 driven by a motor (not numbered). The axle 13 is coaxially connected to the platform 20. Thus, the motor rotates the platform 20 via the axle 13. A slip ring can be used to keep the electrodes electrically connected to the electrostatic generator in the rotation of the platform 20.

The lifting unit includes a support 24 driven by a pneumatic cylinder (not numbered). The pneumatic cylinder can be replaced with a hydraulic cylinder in another embodiment.

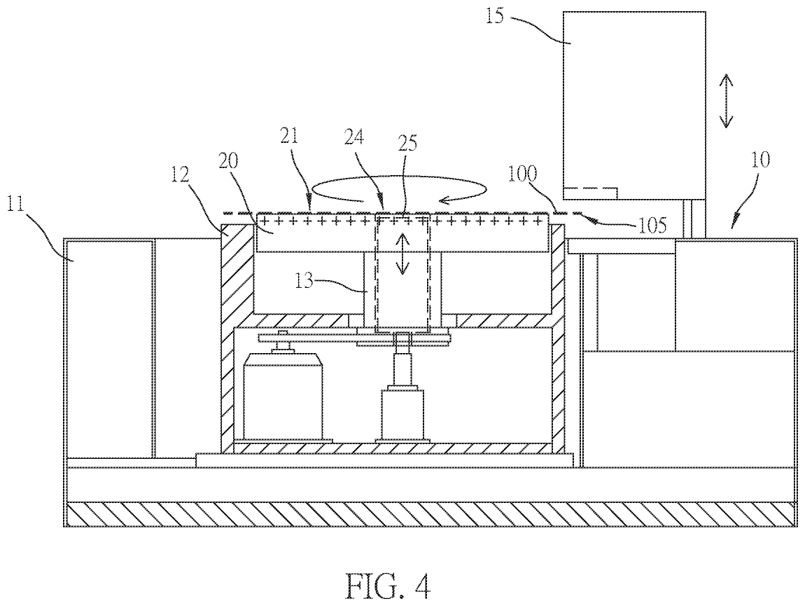

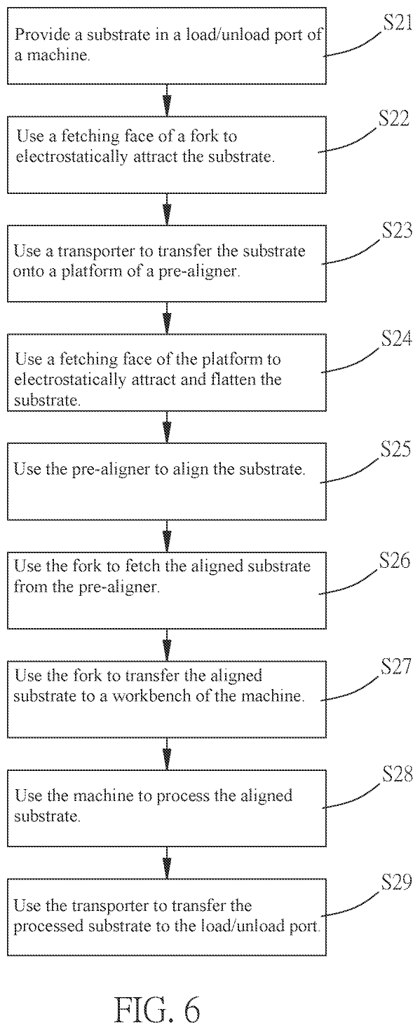

The support 24 preferably includes a single rod coaxially inserted in the axle 13, which is a hollow element. The support 24 can include three rods in another embodiment. The support 24 includes a fetching face 25 at an upper end. Electrodes (not numbered) are arranged on the fetching face 25. The electrodes enable the fetching face 25 to attract the substrate 100 electrostatically. The support 24 is extensible through an aperture centrally made in the platform 20 so that the fetching face 25 is movable between a lower position and an upper position without interfering with the rotation of the platform 20. In the lower position, the fetching face 25 is coplanar with or lower than the fetching face 21 (FIG. 4). In the upper position, the fetching face 25 is higher than the fetching face 21 (FIG. 7).

The sensing unit 15 senses the substrate 100. The sensing unit 15 can be an optical, imagery or mechanical sensing unit.

Referring to FIG. 3, the transporter 30 is preferably a robot with six or seven axes. The transporter 30 includes a fork 31 or any other end-effector for translation and rotation. At least one of two opposite faces of the fork 31 is a fetching face 32 provided with electrodes (not numbered) for generating an electrostatic field on the fetching face 32 of the fork 31 to enable the fetching face 32 to electrostatically attract the substrate 100. Thus, the substrate 100 kept in position relative to the fork 31 during their movement.

As discussed above, the fetching face 32 and the contact 21 can fetch the substrate 100 that is as thin as 200 micrometers or thinner. Thus, the machine 500 can firmly handle the substrate 100. Moreover, the fetching face 21 can keep the substrate 100 flat to allow proper processing on the substrate 100.

To align the substrate 100, the machine 500 executes a process to be described referring to FIG. 6.

At S21, the substrate 100 is provided in the load/unload port 505 of the machine 500.

At S22, the fetching face 32 of the fork 31 electrostatically attracts the substrate 100.

At S23, the transporter 30 transfers the substrate 100 onto the platform 20 of the pre-aligner 10. In the beginning, the cylinder 33 moves the support 24 to the upper position. Then, the fork 31 moves the substrate 100 to a position above the support 24. Then, the fork 31 descends, thereby transferring the substrate 100 onto the support 24. Then, the fetching face 25 attracts the substrate 100 electrostatically. Then, the fork 31 leaves the pre-aligner 10. Then, the pneumatic cylinder 33 moves the support 24 to the lower position, thereby laying the substrate 100 onto the platform 20.

In another embodiment, while moving to the upper position, the support 24 moves beyond the fork 31. Thus, support 24 takes the substrate 100 from the fork 31 without having to lower the fork 31.

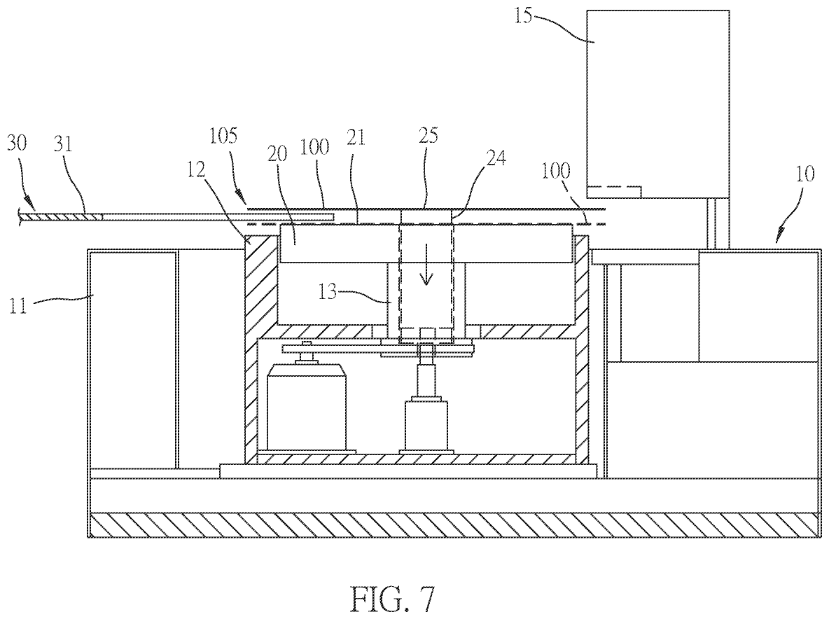

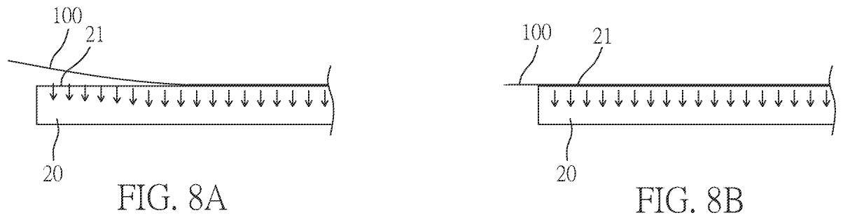

At S24, the fetching face 21 of the platform 20 electrostatically attracts and flattens the substrate 100. To this end, the electrodes 22 generate an electrostatic field on the fetching face 21 to attract the substrate 100. Moreover, the fetching face 21 flattens the substrate 100 (FIG. 8B) even if the substrate 100 originally suffers grave warpage (FIG. 8A). Hence, even the portion of the substrate 100 that extends beyond the fetching face 21 is coplanar with the other portion of the substrate 100.

At S25, the pre-aligner 10 aligns the substrate 100.

At S26, the fork 31 fetches the aligned substrate 100 from the pre-aligner 10.

At S27, the fork 31 transfers the aligned substrate 100 to the workbench 501 of the machine 500.

At S28, the machine 500 processes the aligned substrate 100.

At S29, the transporter 30 transfers the processed substrate 100 to the load/unload port 505.

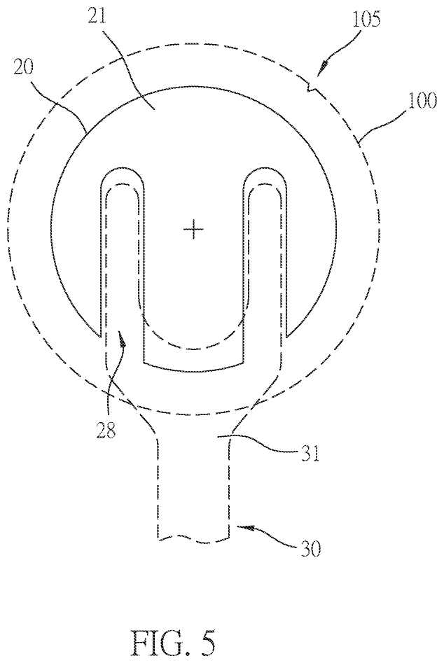

Referring to FIG. 5, there is shown a pre-aligner 10 according to a second embodiment of the present invention. The second embodiment is like the first embodiment except for two things. Firstly, the support 24 and the pneumatic cylinder 33 are omitted. Secondly, the platform 20 includes two slits 28. The slits 28 are located and shaped corresponding to two prongs of the fork 31 of the robot.

To transfer the substrate 100 onto the platform 20 from the fork 31, the fork 31 is moved to a position above the platform 20. Now, the substrate 100 is located above the platform 20. Then, the fork 31 is lowered to a position below the platform 20 as the prongs of the fork 31 are inserted in the slits 28. Thus, the substrate 100 is transferred onto the platform 20 from the fork 31. Then, the fork 31 is moved from the pre-aligner 10, i.e., the prongs of fork 31 are moved from the slits 28.

The foregoing process is reversed to transfer the substrate 100 to the fork 31 from the platform 20. Then, the substrate 100 can undergo other tasks.

The electrodes are used on the fetching faces 21, 25 and 32 to generate electrostatic fields to attract the substrate 100. Hence, the fetching faces 21, 25 and 32 properly attract the substrate 100 even if the substrate 100 suffers grave warpage. Furthermore, the fetching face 21 flattens the substrate 100 to allow effective alignment of the substrate 100. Moreover, there is substantially no risk of damaging the substrate 100 during the transfer and alignment of the substrate 100.

The present invention has been described via the illustration of the embodiments. Those skilled in the art can derive variations from the embodiments without departing from the scope of the present invention. Therefore, the embodiments shall not limit the scope of the present invention defined in the claims.

1. A loader comprising:
a pre-aligner comprising:
a base;
a moving mechanism comprising an axle inserted in the base;
a platform coaxially connected to the axle and formed with a fetching face operable for generating an electrostatic field to attract a substrate; and
a sensing unit located on the base and operable for sensing an orienting portion of the substrate; and
a transporter comprising a fork formed with a fetching face operable for generating an electrostatic field to attract the substrate.

2. The loader according to claim 1, wherein the moving mechanism is operable to move the platform relative to the sensing unit, thereby moving the substrate relative to the sensing unit.

3. The loader according to claim 1, wherein the platform does not reach the orienting portion of the substrate, and a diameter of the platform is larger than one third of a diameter of the substrate to allow the platform to render the entire substrate flat.

4. The loader according to claim 1, further comprising a support movable between a lower position coplanar with or lower than the platform and an upper position higher than the platform, wherein the platform carries the substrate when the support is in the upper position, and the support carries the substrate when the support is in the upper position.

5. The loader according to claim 4, further comprising a cylinder inserted in the base and formed with a piston rod connected to the support.

6. The loader according to claim 4, wherein the support comprises a fetching face provided with electrodes.

7. The loader according to claim 1, wherein the platform comprises two slits corresponding to two prongs of a fork for bringing the substrate into and from the pre-aligner.

8. The loader according to claim 1, wherein the moving mechanism is operable for moving the platform relative to the sensing unit along an X-axis, a Y-axis and a Z-axis.

9. A method for operating a pre-aligner comprising the steps of:
providing a substrate-processing machine with a load/unload port and a workbench;
providing a pre-aligner;
providing a transporter;
loading the substrate onto the load/unload port;
using the transporter to generate an electrostatic field to attract the substrate and transfer the substrate to the pre-aligner from the load/unload port;
using the pre-aligner to generate an electrostatic field to attract the substrate;
using the pre-aligner to align the substrate;
using the transporter to generate an electrostatic field to attract the substrate; and
using the transporter to transfer the substrate to the workbench from the pre-aligner;
using the substrate-processing machine to processes the substrate; and
using the transporter to transfer the processed substrate to the load/unload port.
